(19) United States
(12) Patent Application Publication
(10) Pub. No.: US 2018/0358211 A1
(43) Pub. Date: Dec. 13, 2018

(54) SUBSTRATE TREATING APPARATUS

(71) Applicant: SEMES CO., LTD., Chungcheongnam-do (KR)

(72) Inventor: Sangmin MUN, Chungcheongnam-do (KR)

(21) Appl. No.: 16/002,978

(22) Filed: Jun. 7, 2018

(30) Foreign Application Priority Data
Jun. 9, 2017 (KR) 10-2017-0072437

(51) Int. Cl. H01J 37/32; H01L 21/67

(52) U.S. Cl. CPC H01J 37/32642; H01L 21/67069; H01J 2237/024; H01J 37/32651; H01J 2237/334; H01J 37/32715

(57) ABSTRACT

Disclosed is a substrate treating apparatus. The substrate treating apparatus includes a chuck configured to support a substrate in a treatment space of a chamber into which a process gas is supplied, and a ring assembly surrounding the chuck, and the ring assembly includes an inner ring located such that a portion of the inner ring surrounds an outer side of the substrate supported by the chuck, an outer ring located to surround the inner ring, and a driver configured to move the outer ring upwards and downwards.

### CROSS-REFERENCE TO RELATED APPLICATIONS

This application claims priority under 35 U.S.C. § 119 to Korean Patent Application No. 10-2017-0072437 filed on Jun. 9, 2017, in the Korean Intellectual Property Office, the disclosures of which are incorporated by reference herein in their entireties.

### BACKGROUND

Embodiments of the inventive concept described herein relate to a substrate treating apparatus, and more particularly, relate to an apparatus for treating a substrate by using plasma.

In order to manufacture a semiconductor device, a desired pattern is formed on au substrate by performing various processes, such as photolithography, etching, ashing, ion implantation, deposition of a thin film, and cleaning. Among them, the etching process is a process of removing a selected heating area of a film formed on a substrate, and includes wet etching and dry etching.

For dry etching, an etching apparatus using plasma is used. Generally, in order to form plasma, an electromagnetic field is formed in an interior space of a chamber and the electromagnetic field excites a process gas provided into the chamber into a plasma state.

Plasma refers to an ionized gaseous state including ions, electrons, and radicals. The plasma is generated by very high temperature, strong electric fields, or radio frequency (RF) electromagnetic fields. In the semiconductor device manufacturing process, an etching process is performed by using plasma. The etching process is performed by colliding the ion particles contained in the plasma with a substrate.

### SUMMARY

Embodiments of the inventive concept provide a substrate treating apparatus that may efficiently treat a substrate.

Embodiments of the inventive concept also provide a substrate treating apparatus that may minimize a change of an interface of a sheath formed around a substrate during use thereof and plasma.

In accordance with an aspect of the inventive concept, there is provided a substrate treating apparatus including a chuck to support a substrate in a treatment space of a chamber into which a process gas is supplied, and a ring assembly surrounding the chuck, wherein the ring assembly includes an inner ring located such that a portion of the inner ring surrounds an outer side of the substrate supported by the chuck, an outer ring located to surround the inner ring, and a driver to move the outer ring upwards and downwards.

The ring assembly may further include an insulating member located between the inner ring and the outer ring.

A lower insulating member may be coupled to a lower end of the outer ring.

A relative location of the inner ring to the chuck may be fixed.

The inner ring and the outer ring may be formed of a conductive material.

The substrate treating apparatus may further include a metallic coupler located between the inner ring and the chuck, and the inner ring is fixed to the coupler.

The ring assembly may further include a shield member located to surround the outer ring.

The inner ring may include a gradient part, an inner side of which is higher than an outer side of the gradient part.

An inner side of the outer ring may be higher than an outer side of the inner ring.

The outer ring may include an upper protrusion, an upper side of which protrudes inwards, and the upper protrusion covers a vertically upper side of the insulating member.

The inner ring may include a lower protrusion, a lower side of which protrudes outwards, and the insulating member is located on the lower protrusion.

The outer ring may adjust an interface between plasma generated from the process gas and a sheath.

The insulating member may prevent an arc from being generated between the inner ring and the outer ring.

### BRIEF DESCRIPTION OF THE FIGURES

The above and other objects and features of the inventive concept will become apparent by describing in detail exemplary embodiments thereof with reference to the accompanying drawings.

FIG. 1 is a view illustrating a substrate treating apparatus according to an embodiment of the inventive concept;

FIGS. 2 to 4 is a view illustrating a ring assembly according to a first embodiment;

FIGS. 2 and 3 are views illustrating a change of an interface between a sheath formed around a ring assembly and a plasma interface according to use of the substrate treating apparatus;

FIG. 4 is a view illustrating a state in which an outer ring is lifted;

FIG. 5 is a view illustrating a ring assembly according to a second embodiment;

FIG. 6 is a view illustrating a ring assembly according to a modification of FIG. 5;

FIG. 7 is a view illustrating a ring assembly according to another modification of FIG. 5;

FIG. 8 is a view illustrating a ring assembly according to a third embodiment; and

FIG. 9 is a view illustrating a state in which an outer ring is lifted in FIG. 8.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

In the embodiment of the inventive concept, a substrate treating apparatus for treating a substrate by generating plasma in an inductively coupled plasma scheme (ICP) scheme will be described. However, the inventive concept is not limited thereto, and may be applied to various kinds of apparatuses that treat a substrate by using plasma, for example, by using a conductively coupled plasma (CCP) scheme or a remote plasma scheme.

Further, in the embodiment of the inventive concept, an electrostatic chuck will be described as an example of a support unit. However, the inventive concept is not limited thereto and the support unit may support a substrate through mechanical clamping or by using vacuum.

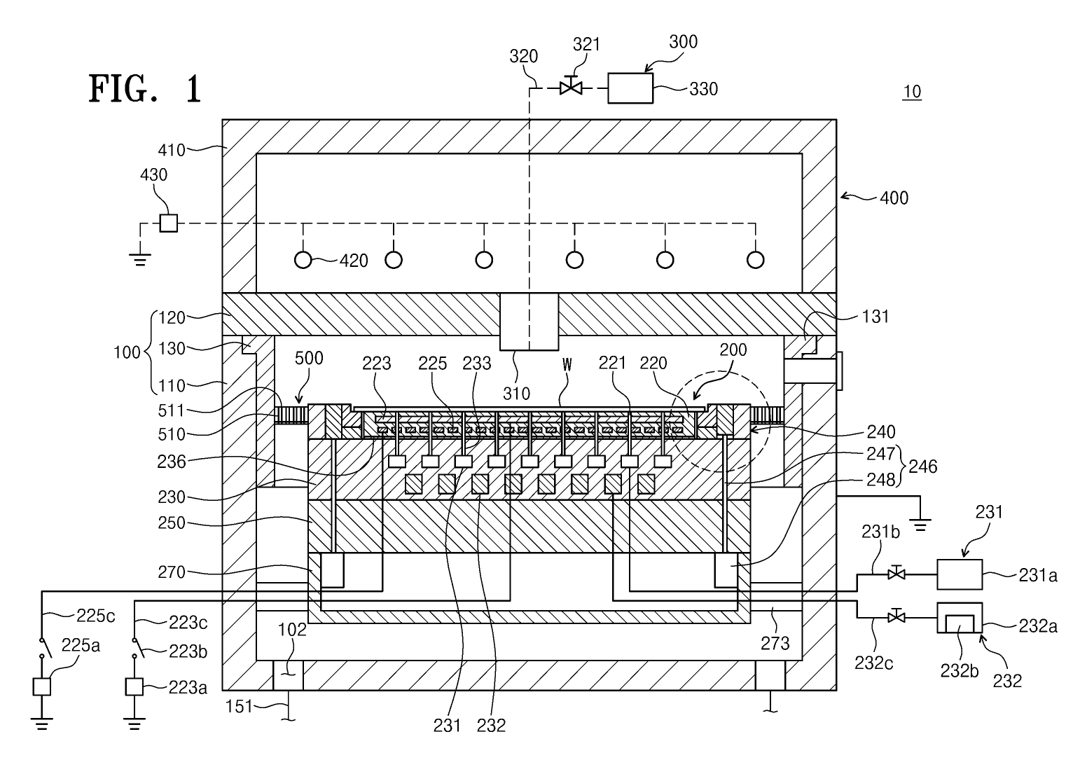

FIG. 1 is a view illustrating a substrate treating apparatus according to an embodiment of the inventive concept.

Referring to FIG. 1, the substrate treating apparatus 10 treats a substrate W by using plasma. For example, the substrate treating apparatus 10 may perform an etching process on the substrate W. The substrate treating apparatus 10 may include a chamber 100, a support unit 200, a gas supply unit 300, a plasma source 400, and an exhaustion unit 500.

The chamber 100 has a treatment space in which a substrate is treated in the interior thereof. The chamber 100 includes a housing 110, a cover 120, and a liner 130.

The housing 110 has an open-topped space in the interior thereof. The interior space of the housing 110 is provided as a treatment space in which a substrate treating process is performed. The housing 110 is formed of a metallic material. The housing 110 may be formed of aluminum. The housing 110 may be grounded. An exhaust hole 102 is formed on a bottom surface of the housing 110. The exhaust hole 102 is connected to an exhaust line 151. The reaction side-products generated in the process and gases left in the interior space of the housing 110 may be discharged to the outside through the exhaust line 151. Through the exhaustion process, the pressure of the interior of the housing 110 is reduced to a specific pressure.

The cover 120 covers an opened upper surface of the housing 110. The cover 120 has a plate shape, and the interior space of the housing 110 is closed. The cover 120 may include a dielectric substance window.

The liner 130 is provided in the interior of the housing 110. The liner 130 has an interior space, an upper surface and a lower surface of which are opened. The liner 130 may have a cylindrical shape. The liner 130 may have a radius corresponding to an inner surface of the housing 110. The liner 130 is provided along the inner surface of the housing 110. A support ring 131 is formed at an upper end of the liner 130. The support ring 131 is a ring-shaped plate, and protrudes to the outside of the liner 130 along the circumference of the liner 130. The support ring 131 is positioned at an upper end of the housing 110, and supports the liner 130. The liner 130 may be formed of the same material as the housing 110. The liner 130 may be formed of aluminum. The liner 130 protects the inner surface of the housing 110. For example, in a process of exciting a process gas, arc discharging may be generated in the interior of the chamber 100. The arc discharging damages peripheral devices. The liner 130 prevents an inner surface of the housing 110 from being damaged due to arc discharging by protecting the inner surface of the housing 110. Further, the reaction side-products generated in the substrate treating process are prevented from being deposited on the inner wall of the housing 110. The liner 130 is inexpensive and may be easily exchanged as compared with the housing 110. Accordingly, when the liner 130 is damaged due to arc discharging, the operator may exchange the liner 130 with a new liner 130.

The support unit 200 supports the substrate in the treatment space in the interior of the chamber 100. For example, the support unit 200 is disposed in the interior of the housing 110. The support unit 200 supports the substrate W. The support unit 200 may be provided in an electrostatic chuck scheme of suctioning the substrate W by using an electrostatic force. Unlike this, the support unit 200 may support the substrate W in various methods such as mechanical clamping. Hereinafter, the support unit 200 provided in an electrostatic chuck scheme will be described.

The support unit 200 includes a chuck 220, 230, and 250 and a ring assembly 240.

The chuck 220, 230, and 250 supports a substrate during a process. The chuck 220, 230, and 250 includes a support plate 220, a passage forming plate 230, and an insulating plate 250.

The support plate 220 is located at an upper end of the support unit 200. The support plate 220 may be formed of a dielectric substance of a disk shape. The substrate W is positioned on the upper surface of the support plate 220. The upper surface of the support plate 220 has a diameter that is smaller than that of the substrate W. A first supply passage 221 that is used as a passage, through which a heat transfer gas is supplied to a bottom surface of the substrate W, is formed in the support plate 220. An electrostatic electrode 223 and a heater 225 are buried in the support plate 220.

The electrostatic electrode 223 is located above the heater 225. The electrostatic electrode 223 is electrically connected to a first lower power source 223a. An electrostatic force is applied between the electrostatic electrode 223 and the substrate W by a current applied to the electrostatic electrode 223, and the substrate W is suctioned to the support plate 220 by the electrostatic force.

The heater 225 is electrically connected to a second lower power source 225a. The heater 225 generates heat by a resistance due to a current applied to the second power source 225a. The generated heat is transferred to the substrate W through the support plate 220. The substrate W is maintained at a preset temperature by the heat generated by the heater 225. The heater 225 includes a spiral coil. A passage forming plate 230 is located below the support plate 220. A bottom surface of the support plate 220 and an upper surface of the passage forming plate 230 may be bonded to each other by an adhesive 236.

The passage forming plate 230 may be located below the support plate 220.

The passage forming plate 230 has a first circulation passage 231, a second circulation passage 232, and a second supply passage 233. The first circulation passage 231 is provided as a passage, through which the heat transfer gas circulates. The second circulation passage 232 is provided as a passage, through which a cooling fluid circulates. The second supply passage 233 connects the first circulation passage 231 and the first supply passage 221. The first circulation passage 231 is provided as a passage, through which the heat transfer gas circulates. The first circulation passages 231 may be formed in the interior of the passage forming plate 230 to have spiral shapes. Further, the first circulation passage 231 may be disposed such that passages having ring shapes of different radii have the same center. The first circulation passages 231 may communicate with each other. The first circulation passages 231 are formed at the same height.

The first circulation passages 231 are connected to a heat transfer medium storage 231a through a heat transfer medium supply lines 231b. A heat transfer medium is stored in the heat transfer medium storage 231a. The heat transfer medium includes an inert gas. According to an embodiment, the heat transfer medium includes a helium (He) gas. The helium gas may be supplied to the first circulation passages 231 through supply lines 231b, and may be supplied to the bottom surface of the substrate W after sequentially passing through the second supply passages 233 and the first supply passages 221. The helium gas functions as a medium that helps exchange of heat between the substrate W and the support plate 220. Accordingly, the temperature of the substrate W becomes uniform as a whole.

The second circulation passages 232 are connected to the cooling fluid storage 232a through the cooling fluid supply lines 232c. The cooling fluid storage 232a may store a cooling fluid. A cooler 232b may be provided in the cooling fluid storage 232a. The cooler 232b cools the cooling fluid to a specific temperature. Unlike this, the cooler 232b may be installed on the cooling fluid supply line 232c. The cooling fluid supplied to the second circulation passages 232 through the cooling fluid supply lines 232c cools the passage forming plate 230 while circulating along the second circulation passages 232. The passage forming plate 230 cools the support plate 220 and the substrate W together while being cooled to maintain the substrate W at a specific temperature. For the above-mentioned reasons, the temperature of a lower portion of the ring assembly 240 is generally lower than the temperature of an upper portion of the ring assembly 240.

The insulation plate 250 is located below the passage forming plate 230. The insulation plate 250 is formed of an insulating material, and electrically insulates the passage forming plate 230 and the lower cover 270.

The lower cover 270 is located at a lower end of the support unit 200. The lower cover 270 is spaced upwards apart from the bottom surface of the housing 110. An open-topped space is formed in the interior of the lower cover 270. The upper surface of the lower cover 270 is covered by the insulation plate 250. Accordingly, the outer radius of the section of the lower cover 270 may be the same as the outer radius of the insulation plate 250. A lift pin or the like that receives the transferred substrate W from a transfer member on the outside and positions the substrate W on the support plate may be located in the interior space of the lower cover 270.

The lower cover 270 has a connecting member 273. The connecting member 273 connects an outer surface of the lower cover 270 and an inner wall of the housing 110. A plurality of connecting members 273 may be provided on an outer surface of the lower cover 270 at regular intervals. The connecting members 273 support the support unit 200 in the interior of the chamber 100. Further, the connecting members 273 are connected to an inner wall of the housing 110 such that the lower cover 270 is electrically grounded. A first power line 223c connected to the first lower power source 223a, a second power line 225c connected to the second lower power source 225a, a heat transfer medium supply line 231b connected to the heat transfer medium storage 231a, and a cooling fluid supply line 232c connected to the cooling fluid storage 232a extend into the lower cover 270 through the interior space of the connecting member 273.

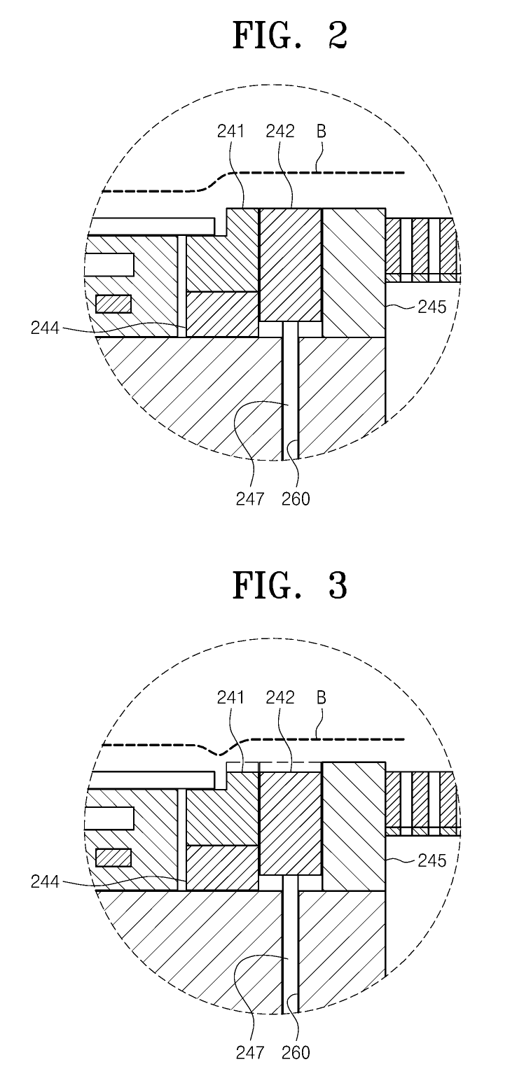

The ring assembly 240 adjusts a sheath and plasma interface B. The ring assembly 240 includes an inner ring 241 (see FIG. 2) and an outer ring 242 (see FIG. 2).

The inner ring 241 is located outside of an upper side of the chuck 220, 230, and 250. The inner ring 241 may surround the support plate 220. The outer surface of the support plate 220 and the inner surface of the inner ring 241 may be spaced apart from each other by a preset distance. The inner ring 241 may have a single configuration of a ring shape. The location of the inner ring 241 is fixed so that the relative location of the inner ring 241 to the chuck 220, 230, and 250 is not changed. The inner ring 241 may be formed of a conductive material. The inner ring 241 may be formed of silicon or silicon carbide.

A coupler 244 may be provided below the inner ring 241. The coupler 244 may fix the inner ring 241 to the passage forming plate 230. The coupler 244 is formed of a thermally conductive material. As an example, the coupler 244 may be formed of a metallic material such as aluminum. Further, the coupler 244 may be bonded to an upper surface of the passage forming plate 230 by a thermally conductive adhesive (not illustrated). Further, the inner ring 241 may be bonded to the upper surface of the coupler 244 by a thermally conductive adhesive (not illustrated). As an example, the thermally conductive adhesive may be a silicon pad.

Further, the coupler 244 may be excluded, and the inner ring 241 may be located to directly contact the chuck 220, 230, and 250.

The outer ring 242 is provided to surround the inner ring 241. The outer ring 242 has a single configuration of a ring shape. The outer ring 242 may be formed of a conductive material. The outer ring 242 may be formed of silicon, silicon carbide or the like. An inner surface of the outer ring 242 and an outer surface of the inner ring 241 may be spaced apart from each other by a preset distance. The spacing distance between the outer ring 242 and the inner ring 241 may be limited to several micrometers or several hundreds of micrometers to prevent introduction of plasma. The outer ring 242 is provided to be movable vertically. As an example, the outer ring 242 may be moved upwards by the driver 246. The driver 246 may include a driving rod 247 and a driving unit 248. The driving rod 247 may be located in a driving hole 260 (see FIG. 2) formed in the chuck 220, 230, and 250 to be located below the outer ring 242. Further, the driving unit 248 may be located at a lower end of the driving rod 247 to lift upper or lower the driving rod 247. The driving rod 247 may be lifted to move towards the outer ring 242. As an example, the driving unit 248 may include a driving converting unit that converts a rotational motion of a motor to a translational motion. As an example, the driving converting unit may include a rack/pinion gear assembly.

A shield member 245 (see FIG. 2) may be located outside the outer ring 242. The shield member 245 may have a ring shape to surround an outer side of the outer ring 242. The shield member 245 prevents a side surface of the outer ring 242 from being directly exposed to plasma or from being introduced plasma into a side of the outer ring 242.

The gas supply unit 300 supplies a process gas into the treatment space in the interior of the chamber 100. The gas supply unit 300 includes a gas supply nozzle 310, a gas supply line 320, and a gas storage unit 330. The gas supply nozzle 310 is installed at a central portion of the cover 120. An ejection hole is formed on the bottom surface of the gas supply nozzle 310. The ejection hole is located below the cover 120, and supplies the process gas into the interior of the chamber 100. The gas supply unit 320 connects the gas supply nozzle 310 and the gas storage unit 330. The gas supply line 320 supplies the process gas stored in the gas storage unit 330 to the gas supply nozzle 310. A valve 321 is installed in the gas supply line 320. The valve 321 opens and closes the gas supply line 320, and adjusts a flow rate of the process gas supplied through the gas supply line 320.

The plasma source 400 generates plasma from a process gas supplied into the treatment space in the interior of the chamber 100. The plasma source 400 is provided outside the treatment space of the chamber 100. According to an embodiment, an inductively coupled plasma (ICP) source may be used as the plasma source 400. The plasma source 400 includes an antenna chamber 410, an antenna 420, and a plasma power source 430. The antenna chamber 410 has an open-bottomed cylindrical shape. The antenna chamber 410 has a space in the interior thereof. The antenna chamber 410 has a diameter corresponding to the chamber 100. A lower end of the antenna chamber 410 may be detachably provided in the cover 120. The antenna 420 is disposed in the interior of the antenna chamber 410. The antenna 420 is a spiral coil that is wound a plurality of times, and is connected to the plasma power source 430. The antenna 420 is supplied with electric power from the plasma power source 430. The plasma source 430 may be located outside the chamber 100. The antenna 420, to which electric power has been applied, may form an electromagnetic field to the treatment space of the chamber 100. The process gas is excited into a plasma state by an electromagnetic field.

The exhaustion unit 500 is located between an inner wall of the housing 110 and the support unit 200. The exhaustion unit 500 includes an exhaustion plate 510 having a through-hole 511. The exhaustion plate 510 has an annular ring shape. The exhaustion plate 510 has a plurality of through-holes 511. The process gas provided into the housing 110 passes through through-holes 511 of the exhaustion plate 510 and is exhausted through the exhaust hole 102. The flow of the process gas may be controlled according to the shape of the exhaustion plate 510 and the shape of the through-holes 511.

Next, a ring assembly according to a first embodiment of the inventive concept will be described with reference to FIGS. 2 to 4.

FIGS. 2 and 3 are views illustrating a change of an interface between a sheath formed around a ring assembly and a plasma interface according to use of the substrate treating apparatus.

Referring to FIGS. 2 and 3, an electric field is also formed between the sheath/plasma interface B and the ring assembly 240, and the inner ring 241 and the outer ring 242 are etched by ions via a process that is similar to that of the substrate W in the process of treating the substrate W. Accordingly, the height of an upper end of the inner ring 241 and the height of an upper end of the outer ring 242 may decreases as the number of uses thereof increases.

If the height of the upper end of the inner ring 241 and the height of the upper end of the outer ring 242 become lower, the sheath/plasma interface B also changes, and accordingly, the electric field also changes.

At this time, the electric field is formed in a direction from the outer side of the substrate W towards the inner side of the substrate W in the region where the outer side of the substrate W and the ring assembly 240 meet.

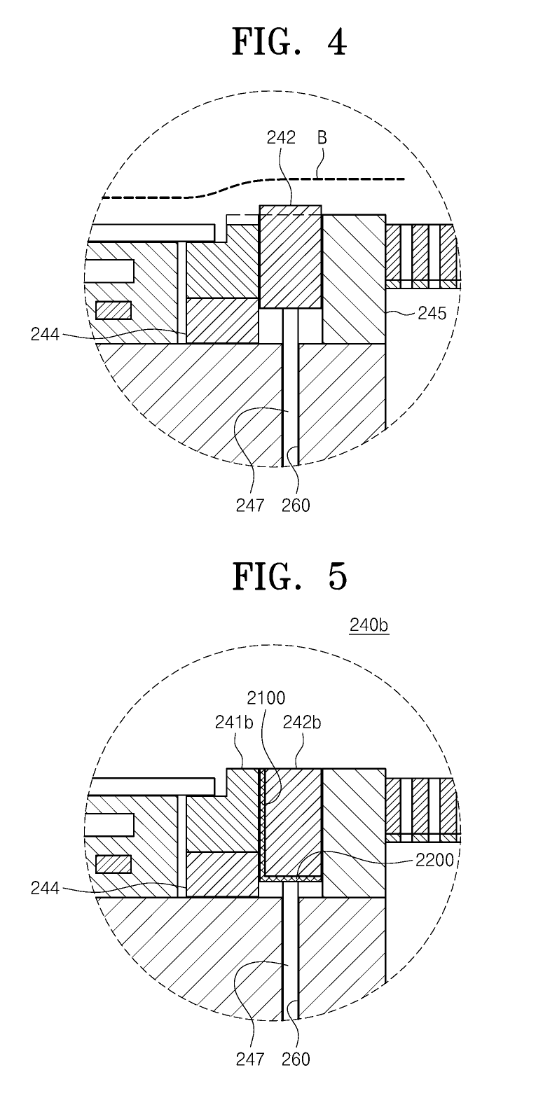

FIG. 4 is a view illustrating a state in which an outer ring is lifted.

Referring to FIG. 4, if the upper ends of the inner ring 241 and the outer ring 242 are etched, the outer ring 242 is moved upwards to offset their influences. As an example, the outer ring 242 may be moved upwards by a preset height whenever a preset number of substrates are treated. If the outer ring 242 is moved upwards, the height by which the upper end of the outer ring 242 is lowered due to the etching is offset so that the sheath/plasma interface B formed above the outer ring 242 is recovered.

The height by which the outer ring 242 is lifted may be adjusted in consideration of the thickness by which the upper side of the outer ring 242 is etched. As an example, the upper side of the outer ring 242 may be moved upwards by the thickness by which the upper side of the outer ring 242 is etched, and the height of the upper surface of the outer ring 242 may be recovered to a height (hereinafter, a reference height) before the etching occurs.

Further, the height by which the outer ring 242 is lifted may be adjusted in consideration of the thickness by which the outer ring 242 and the inner ring 241 are etched. Even though the height of the upper surface of the outer ring 242 is recovered, the influence of the lowering of the height of the upper surface of the inner ring 241 occurs. Accordingly, the outer ring 242 may be moved such that the upper surface of the outer ring 242 may be located above the reference height in consideration of the lowering of the height of the upper surface of the inner ring 241. If the upper surface of the outer ring 242 is located above the reference height, the height of the sheath/plasma interface B formed above the outer ring 242 becomes higher than the ring assembly 240 is etched. Further, the sheath/plasma interface B formed above the outer ring 242 influences the sheath/plasma interface B formed above the inner ring 241 to offset the influence of the etching of the inner ring 241.

During the process, the temperature of the inner ring 241 becomes higher with the influence of the plasma. As the temperature of the inner ring 241 becomes higher, the process gas is concentrated in an area that is adjacent to the inner ring 241. Accordingly, the inner ring 241 fails to maintain a state in which the inner ring 241 contacts the surrounding configurations, and a non-uniformity in which a peripheral area of the substrate W is excessively etched as compared with a central area of the substrate W may be caused if the inner ring 241 is not smoothly cooled. Meanwhile, the substrate treating apparatus according to the inventive concept is provided such that the inner ring 241 is fixed so that the inner ring 241 always contacts the surrounding configurations, and heat is transferred to the chuck 220, 230, and 250. Accordingly, even though the outer ring 242 is moved to adjust the sheath/plasma interface B, the inner ring 241 may be smoothly cooled by the heat transfer.

FIG. 5 is a view illustrating a ring assembly according to a second embodiment.

Referring to FIG. 5, At least one of the outer rings 242b may have a configuration for preventing generation of an arc.

An insulating member 2100 may be located on an inner surface of the outer ring 242b which is adjacent to the inner ring 241b. The insulating member 2100 is formed of an insulating material. The insulating member 2100 may be attached to an inner surface of the outer ring 242b after being made separately, or may be formed by coating the inner surface of the outer ring 242b. The insulating member 2100 prevents an arc from being generated between the outer ring 242b and the inner ring 241b.

A lower insulating member 2200 may be located on the bottom surface of the outer ring 242b. The lower insulating member 2200 is formed of an insulating material. The lower insulating member 2200 may be attached to a lower surface of the outer ring 242b after being made separately, or may be formed by coating the lower surface of the outer ring 242b. The lower insulating member 2200 prevents an arc from being generated between the chuck 220, 230, and 250 and the outer ring 242b.

The configuration and operation of the ring assembly 240b, except for the insulation member 2100 and the lower insulating member 2200, are the same as those of FIGS. 2 to 4, and a description thereof will be omitted.

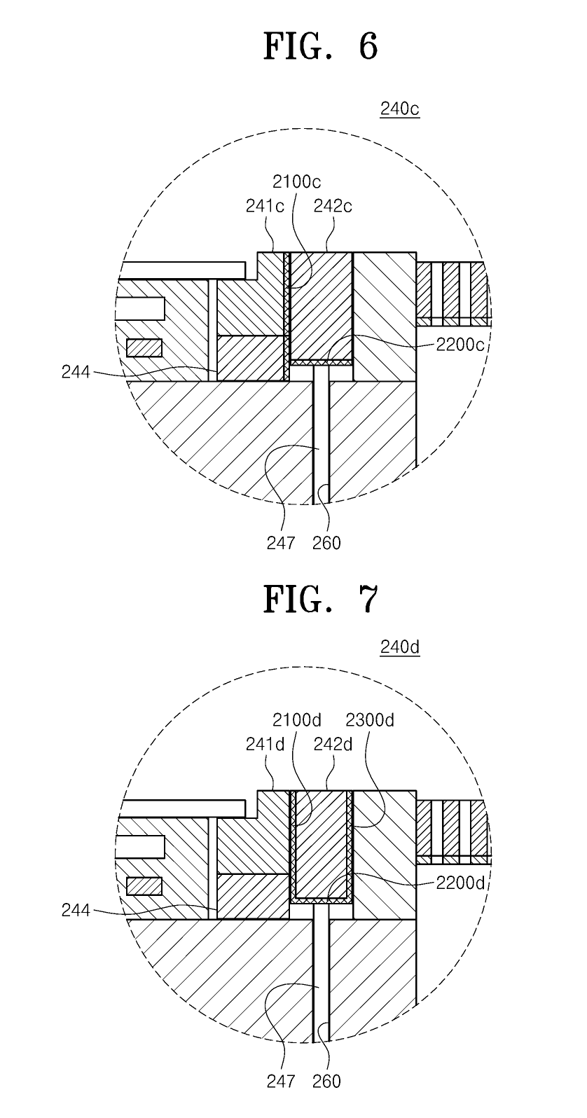

FIG. 6 is a view illustrating a ring assembly according to a modification of FIG. 5.

Referring to FIG. 6, the insulating member 2100c may be provided in a state in which the insulation member 2100c is located on an outer surface of the inner ring 241c. The insulating member 2100c is formed of an insulating material. The insulating member 2100c may be attached to an outer surface of the inner ring 241c after being made separately, or may be formed by coating the outer surface of the inner ring 241c. The insulating member 2100c prevents an arc from being generated between the outer ring 242c and the inner ring 241c.

A lower insulating member 2200c may be located on the bottom surface of the outer ring 242c similarly to FIG. 5.

The configuration and operation of the ring assembly 240c, except for the insulation member 2100c and the lower insulating member 2200c, are the same as those of FIGS. 2 to 4, and a description thereof will be omitted.

FIG. 7 is a view illustrating a ring assembly according to another modification of FIG. 5.

Referring to FIG. 7, an outer insulating member 2300d may be located on an outer surface of the outer ring 242d, which is adjacent to the shield member 245. The outer insulating member 2300d is formed of an insulating material. The outer insulating member 2300d may be attached to an outer surface of the outer ring 242d after being made separately, or may be formed by coating the outer surface of the outer ring 242d. The outer insulating member 2300d prevents an arc from being generated between the outer ring 242d and the insulating member. When the shield member 245 is formed of an insulating material, the insulating member 2300d outside the outer insulating member may be omitted.

The insulating member 2100d may be provided similarly to the insulating member 2100 of FIG. 5 or the insulating member 2100c of FIG. 6.

The lower insulation member 2200d may be provided similarly to the lower insulating member 2200 of FIG. 5.

The configuration and operation of the ring assembly 240d, except for the insulation member 2100d, the lower insulating member 2200d, and the outer insulating member 2300d are the same as those of FIGS. 2 to 4, and a description thereof will be omitted.

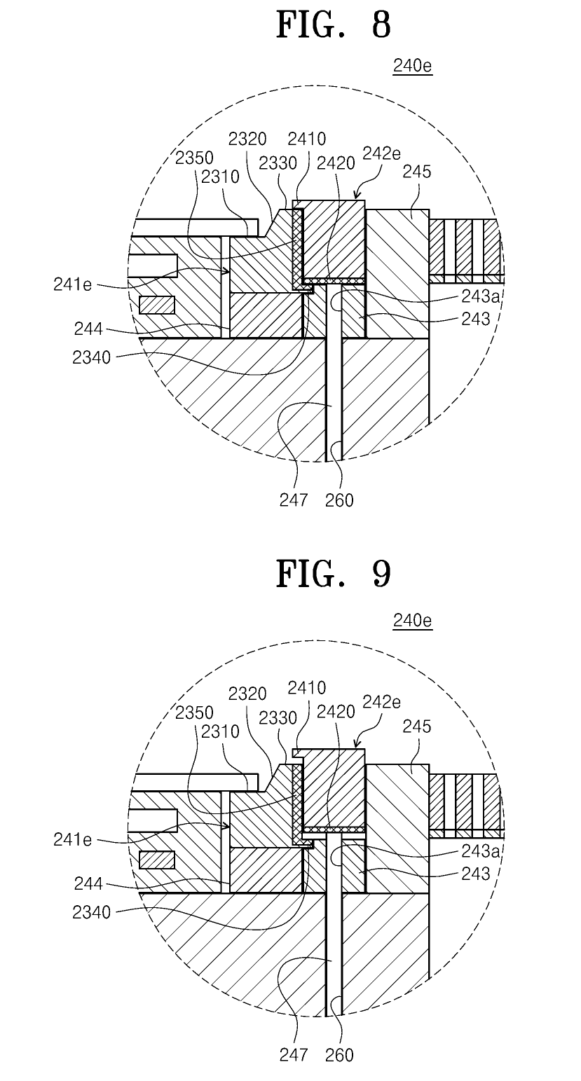

FIG. 8 is a view illustrating a ring assembly according to a third embodiment. FIG. 9 is a view illustrating a state in which an outer ring is lifted in FIG. 8.

Referring to FIGS. 8 and 9, the ring assembly 240e includes an inner ring 241e and an outer ring 242e.

The height of the upper surface of the outside 2330 of the inner ring 241e may be higher than the height of the inner side 2310 of the inner ring 241e. A gradient part 2320 of a preset angle may be formed between the inner side 2310 and the outer side 2330 of the inner ring 241e. The height of the upper side of the inner ring 241e is higher than the height of the radially outer side 2330 so that the plasma may be concentrated in the substrate W by adjusting the sheath/plasma interface and the electric field. A lower protrusion 2340 protruding in the radial direction is formed in the lower portion of the inner ring 241e. A insulating member 2350 may be positioned on the surface facing the outer ring 242e over the outer surface of the inner ring 241e and the lower protrusion 2340. Further, the insulating member 2350 may have a shape that corresponds to the outer surface of the inner ring 241e and the upper surface of the lower protrusion 2340, and may be attached to be located on the upper surface of the lower protrusion 2340.

The insulating member 2350 prevents an arc from being generated between the inner ring 241e and the outer ring 242e.

An upper protrusion 2410 that protrudes inwards is formed on an upper side of the outer ring 242e. The protrusion degree of the upper protrusion 2410 corresponds to the thickness of the insulating member 2350, and the upper protrusion 2410 may be located above the insulating member 2350. The upper protrusion 2410 may be located on the upper surface of the inner ring 241e, and the upper surface of the outer ring 242e may be located to be higher than the outer side of the inner ring 241e by a preset height. Although it is illustrated in the drawings that a side surface of the upper protrusion 2410 is vertical, the side surface of the upper protrusion 2410 may be inclined at a preset angle similarly to the gradient part 2320 of the inner ring 241e. A lower insulating member 2420 may be located below the outer ring 242e. The lower insulating member 2420 prevents an arc from being generated below the outer ring 242e. A border of the outer ring 242e, which is adjacent to the inner ring 242e, have a bent shape due to the upper protrusion 2410 and the lower protrusion 2340 to prevent intrusion of plasma.

An auxiliary ring 243 may be located below the outer ring 242e to fill a space formed on the outside of the coupler 244. The auxiliary ring 243 may have a hole 243a in which the driving rod 247 is located.

Further, the auxiliary ring 243 may be excluded, and the coupler 244 may extend to the lower side of the outer ring 242e.

According to an embodiment of the inventive concept, a substrate treating apparatus that efficiently treats a substrate may be provided.

Further, according to an embodiment of the inventive concept, a substrate treating apparatus that minimizes a change of an interface between a sheath formed around a substrate during use thereof and plasma may be provided.

According to an embodiment of the inventive concept, a substrate treating apparatus that prevents an arc from being generated between configurations may be provided.

The above description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a chuck to support a substrate in a treatment space of a chamber into which a process gas is supplied; and
a ring assembly surrounding the chuck,
wherein the ring assembly includes:
an inner ring located such that a portion of the inner ring surrounds an outer side of the substrate supported by the chuck;
an outer ring located to surround the inner ring; and
a driver to move the outer ring upwards and downwards.

2. The substrate treating apparatus of claim 1, wherein the ring assembly further includes:
an insulating member located between the inner ring and the outer ring.

3. The substrate treating apparatus of claim 2, wherein a lower insulating member is coupled to a lower end of the outer ring.

4. The substrate treating apparatus of claim 1, wherein a relative location of the inner ring to the chuck is fixed.

5. The substrate treating apparatus of claim 1, wherein the inner ring and the outer ring are formed of a conductive material.

6. The substrate treating apparatus of claim 4, further comprising:
a metallic coupler located between the inner ring and the chuck,
wherein the inner ring is fixed to the coupler.

7. The substrate treating apparatus of claim 1, wherein the ring assembly further includes:
a shield member located to surround the outer ring.

8. The substrate treating apparatus of claim 1, wherein the inner ring includes a gradient part, an inner side of which is higher than an outer side of the gradient part.

9. The substrate treating apparatus of claim 1, wherein an inner side of the outer ring is higher than an outer side of the inner ring.

10. The substrate treating apparatus of claim 2, wherein the outer ring includes an upper protrusion that protrudes inwards, and the upper protrusion covers a vertically upper side of the insulating member.

11. The substrate treating apparatus of claim 2, wherein the inner ring includes a lower protrusion, a lower side of which protrudes outwards, and the insulating member is located on the lower protrusion.

12. The substrate treating apparatus of claim 1, wherein the outer ring adjusts an interface between plasma generated from the process gas and a sheath.

13. The substrate treating apparatus of claim 2, wherein the insulating member prevents an arc from being generated between the inner ring and the outer ring.
